(19) United States
(12) Patent Application Publication
(10) Pub. No.: US 2004/0084784 A1
(43) Pub. Date: May 6, 2004

(54) Packaged electronic component and method for packaging an electronic component

(76) Inventors: Stefan Mueller, Wasserburg (DE); Frieder Haag, Reutlingen (DE)

Correspondence Address: KENYON & KENYON, ONE BROADWAY, NEW YORK, NY, 10004, US

(21) Appl. No.: 10/432,943

(22) PCT Filed: Nov. 21, 2001
(86) PCT No.: PCT/DE01/04394

(30) Foreign Application Priority Data
Nov. 25, 2000 (DE) 100 58 593.0

(51) Int. Cl. H01L 21/48; H01L 23/29

(52) U.S. Cl. 257/788; 257/790; 438/124; 257/791; 438/126

(57) ABSTRACT

A packaged electronic component and a method for packaging an electronic component are proposed, in which a chip is attached to the upper side of a die pad. The die pad and the chip are enclosed by a plastic molding compound. A gel is disposed on the upper side of the chip and on the lower side of the die pad.

### FIELD OF THE INVENTION

The present invention is based on a packaged electronic component and a method for packaging an electronic component.

### BACKGROUND INFORMATION

Packaged electronic components are already known, in which a semiconductor chip is attached to an upper side of a die pad of a leadframe. In a subsequent step, the die pad and the chip and further parts of the leadframe are enclosed by a plastic molding compound, thereby producing a hermetic packaging for the chip.

### SUMMARY OF THE INVENTION

In contrast, the electronic component packaged according to the present invention and the method of the present invention for packaging an electronic component have the advantage that mechanical stresses resulting from the different thermal expansion coefficients of the plastic molding compound, of the die pad and of the semiconductor chip are reduced.

Further advantages and improvements are yielded by the measures in the dependent claims. In particular, a silicone gel or fluorosilicone gel is advantageously used. A thermoplastic material, which may be processed by injection molding, is used particularly easily as a plastic molding compound enclosing the chip. The gel should then have a suitable temperature stability. The gel may optionally be applied first on a first side, and subjected to a curing process before the application of a gel on a second side. Thus, nearly all types of gel may be used. Suitably viscous gels may also be applied on two sides, and only thereafter undergo a curing process. In this context, gels may particularly easily be used which cure or are activated under the influence of ultraviolet light, or already cure at room temperature.

### BRIEF DESCRIPTION OF THE DRAWINGS

FIG. 1 shows a conventional packaged electronic component.

FIG. 2 shows an electronic component packaged according to the present invention.

### DETAILED DESCRIPTION

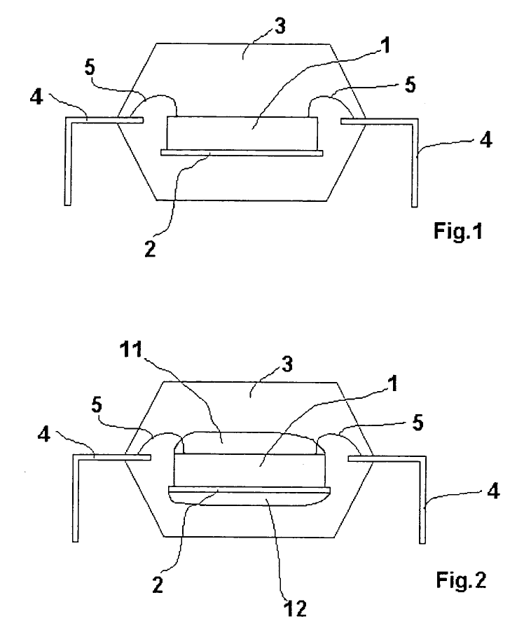

FIG. 1 shows a cross-section through a conventional electronic component. The electronic component has a semiconductor chip 1 disposed on a metallic die pad 2. The upper side of semiconductor chip 1 is electrically connected to printed circuit trace elements 4 by bonding wires 5. Semiconductor chip 1, die pad 2, bonding wires 5, and partially also printed circuit trace elements 4, are surrounded by a plastic molding compound 3 which forms the actual packaging of the electronic component. Therefore, observed from the outside, the electronic component is made of plastic molding compound 3, out of which printed circuit trace elements 4 are brought. Printed circuit trace elements 4 are usually bent downward, to permit attachment to a printed circuit board.

To produce such components, a so-called leadframe, having printed circuit trace elements 4 and die pad 2, is usually punched out of a metal strip. The packaging is then implemented by attaching semiconductor chip 1 to die pad 2 by bonding, soldering or the like, and drawing bonding wires between the upper side of semiconductor chip 1 and printed circuit trace elements 4. This device is then embedded in plastic molding compound 3, which is usually carried out by injection molding. To that end, the leadframe with die pad 2 and, in part, printed circuit trace elements 4, together with semiconductor chip 1 positioned on die pad 2, is brought into a mold, and the mold is filled with a plastic molding compound. Usually, a thermoplastic material is used for this purpose, which, by heating, is brought into a condition in which it may be pressed into the mold in order to fill up the hollow space in the mold. After plastic molding compound 3 has hardened, the electronic component is then removed from the mold.

The problem with this is that different materials are used. The thermal expansion coefficient of the customary semiconductor materials, e.g. silicon, differs markedly from the thermal expansion coefficients of most metals and from the thermal expansion coefficients of the plastic materials for the packaging of semiconductor chips. To minimize the stresses between the semiconductor chip and the material of die pad 2, metallic materials may be used for die pad 2 which have a thermal expansion coefficient that is close to silicon (e.g. FeNi 42%). However, no materials are available for plastic molding compound 3 which, from their thermal expansion coefficient, are adapted to the thermal expansion coefficient of semiconductor chip 1.

FIG. 2 now shows a cross-section through an electronic component packaged according to the present invention. Reference numerals 1 through 5 again designate the same elements as in FIG. 1. However, in contrast to FIG. 1, a gel 11, 12 is applied on the upper side of semiconductor chip 1 and on the lower side of die pad 2. Gel 11, 12 is a material that is easily deformable, and therefore is able to exert only very small forces on semiconductor chip 1. In particular, gel 11, 12 is not capable of transferring deformations of plastic molding compound 3 to semiconductor chip 1. The thermally caused deformation of plastic molding compound 3 relative to semiconductor chip 1 is therefore unable to generate significant forces in semiconductor chip 1. Consequently, the thermal movements of plastic molding compound 3 and of semiconductor chip 1 are decoupled, which means thermally caused strains in semiconductor chip 1 are avoided.

Gel 11, 12 is applied in a liquid state, it being possible to suitably adjust the viscosity of the gel during the application. After gel 11, 12 is applied, a curing step is carried out, in which the elasticity of the gel is changed from a more low-viscosity state during the application to a somewhat more high-viscosity final state. Alternatively, gel 11 may first be applied on one side, e.g. the upper side, of the semiconductor chip, and a curing step then carried out. After this curing step, the leadframe may be turned so that the lower side of die pad 2 then points upward. Gel 12 is then applied on the lower side of the die pad, followed by a curing step. Alternatively, however, it is also possible to coat both sides, i.e. both the upper side of semiconductor chip 1 and the lower side of die pad 2, with a somewhat more low-viscosity gel, and only after that to adjust the final state of gel layers 11, 12 by a curing step. To that end, however, it is necessary that the gel already be sufficiently viscous in the uncured state, and have an adequate adhesion. Gels may be used which cure at room temperature, or cure under UV light, or for which the curing is activated by UV light.

What is claimed is:

1. A packaged electronic component, in which a chip (1) is attached to an upper side of a die pad (2) of a leadframe, and the die pad (2) and the chip (1) are enclosed by a plastic molding compound (3),
wherein a gel (11, 12) is disposed on an upper side of the chip (1) and on a lower side of the die pad (2).

2. The component as recited in claim 1,
wherein a silicone gel or fluorosilicone gel is used for the gel (11, 12).

3. The component as recited in one of the preceding claims,
wherein a thermoplastic material is used for the plastic molding compound (3).

4. The component as recited in one of the preceding claims,
wherein the gel (11, 12) given a temperature stability at which the plastic molding compound (3) may be processed by injection molding.

5. The component as recited in one of the preceding claims,
wherein the chip has a micromechanical component.

6. A method for packaging an electronic component, in which a chip (1) is applied on a die pad (2) of a leadframe and embedded in a plastic molding compound (3),
wherein prior to the embedding process, a gel (11, 12) is applied on an upper side of the chip (1) and on a lower side of the die pad (2).

7. The method as recited in claim 6,
wherein the gel (11, 12) is applied first on one side, a curing step for the gel (11, 12) is thereupon carried out, and only after that is gel (11, 12) applied on another side.

8. The method as recited in claim 6,
wherein gel (11, 12) is applied both on the upper side of the chip (1) and on the lower side of the die pad (2), and a curing step for the gel (11, 12) is thereupon carried out.

9. The method as recited in claim 7 or 8,
wherein a gel (11, 12) is used which cures at room temperature, cures under UV light, or for which the curing is activated by UV light.

10. (New) A packaged electronic component, comprising:
a die pad of a leadframe;
a chip attached to an upper side of the die pad;
a plastic molding compound enclosing the die pad and the chip; and
a gel disposed on an upper side of the chip and on a lower side of the die pad.

11. (New) The component as recited in claim 1, wherein:
the gel includes one of a silicone gel and a fluorosilicone gel.

12. (New) The component as recited in claim 1, wherein:
the plastic molding compound includes a thermoplastic material.

13. (New) The component as recited in claim 1, wherein:
the gel provides a temperature stability at which the plastic molding compound may be processed by injection molding.

14. (New) The component as recited in claim 1, wherein:
the chip includes a micromechanical component.

15. (New) A method for packaging an electronic component, comprising:
applying a chip on a die pad of a leadframe;
embedding the chip and the die pad in a plastic molding compound; and
prior to the embedding, applying a gel on an upper side of the chip and on a lower side of the die pad.

16. (New) The method as recited in claim 15, wherein the step of applying the gel includes:
performing a first applying of the gel by applying the gel first to one of the upper side and the lower side,
after the first applying of the gel, curing the gel, and
after the curing, performing a second applying of the gel by applying the gel to another one of the upper side and the lower side.

17. (New) The method as recited in claim 15, wherein the step of applying the gel includes:
applying gel to both the upper side and the lower side, and after applying the gel to both the upper side and the lower side, curing the gel.

18. (New) The method as recited in claim 16, wherein:
the gel cures one of at room temperature and under UV light.

19. (New) The method as recited in claim 17, wherein:
the gel cures one of at room temperature and under UV light.
